(19) United States
(12) Patent Application Publication
(10) Pub. No.: US 2021/0249077 A1
(43) Pub. Date: Aug. 12, 2021

(54) OPTOELECTRONIC DEVICE AND MEMORY DEVICE

(71) Applicant: NATIONAL CHENG KUNG UNIVERSITY, Tainan City (TW)

(72) Inventors: Jan-Chi YANG, Tainan City (TW); I-Chun CHEN, Tainan City (TW); Yi-De LIOU, Changhua County (TW)

(73) Assignee: NATIONAL CHENG KUNG UNIVERSITY

(21) Appl. No.: 16/861,904

(22) Filed: Apr. 29, 2020

(30) Foreign Application Priority Data
Feb. 6, 2020 (TW) 109103635

(51) Int. Cl. G11C 13/04; G02F 1/01

(52) U.S. Cl. CPC G11C 13/047; G02F 1/0147

(57) ABSTRACT

The present invention relates to an optoelectronic device. The optoelectronic device disclosed in the present invention includes: a carrier; and a light controllable layer patterned to be formed on the carrier, so as to form at least one light controllable element, where the at least one light controllable element is independently controllable by a light beam, so that the at least one light controllable element is switchable between two or more states.

### BACKGROUND OF THE INVENTION

### 1. Field of the Invention

The present invention relates to an optical control optoelectronic device, and in particular, to an optical control memory device.

### 2. Description of the Related Art

For a computer memory, a voltage signal is used to write data into the memory or to modify data. Each memory unit may have two different states of “1” representing a high potential and “0” representing a low potential. Therefore, storage capacity of the memory may be increased by increasing a total number of memory units within the memory. However, increasing the number of memory units also results in the increase of the volume of the memory.

In addition, a computer memory may be divided into a volatile memory or a non-volatile memory, depending on whether the switch-off of the power of the memory has an influence on the data stored therein. A volatile memory is a memory that loses the data stored therein when the power is turned off, while a non-volatile memory is a memory that can still store data when the power is turned off Although a non-volatile memory can still store data after the power is turned off, data loss may still occur due to a problem such as current leakage.

Therefore, there is a need for a memory device that has an increased memory storage density and avoid data loss caused by current or voltage control.

### SUMMARY OF THE INVENTION

An embodiment of the present invention provides an optoelectronic device, including: a carrier; and a light controllable layer patterned to be formed on the carrier, so as to form at least one light controllable element, where the at least one light controllable element is independently controllable by a light beam, so that the at least one light controllable element is switchable between two or more states.

### BRIEF DESCRIPTION OF THE DRAWINGS

Exemplary embodiments are described with reference to the accompanying drawings in this specification. In the accompanying drawings:

FIG. 1A to FIG. 1E are a flowchart of an optical control method according to the present invention;

FIG. 2A to FIG. 2C are a schematic diagram of the principle of a flexoelectric effect;

FIG. 3 shows a relationship between a strain gradient and an electric dipole moment in a light controllable layer after illumination;

FIG. 4 is a schematic diagram of applying a flexoelectric effect theoretical model to a light controllable layer in FIG. 1E; and

FIG. 5A to FIG. 5C are a schematic diagram of a property change of a light controllable layer when an incident position of a light beam is changed.

### PREFERRED EMBODIMENT OF THE PRESENT INVENTION

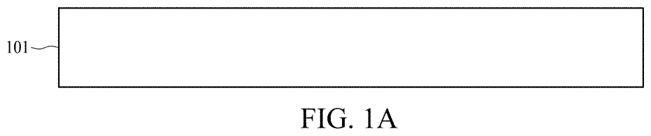

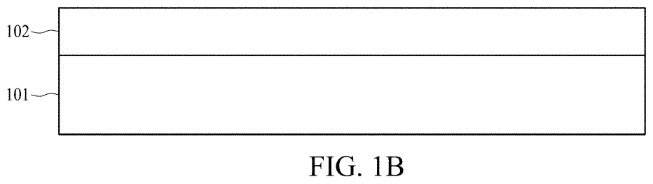

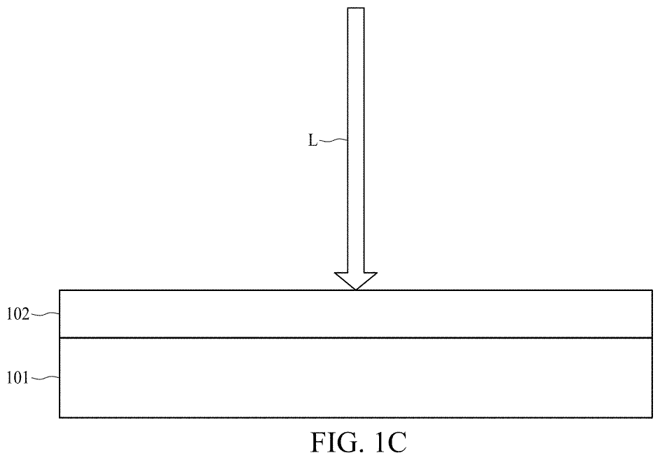

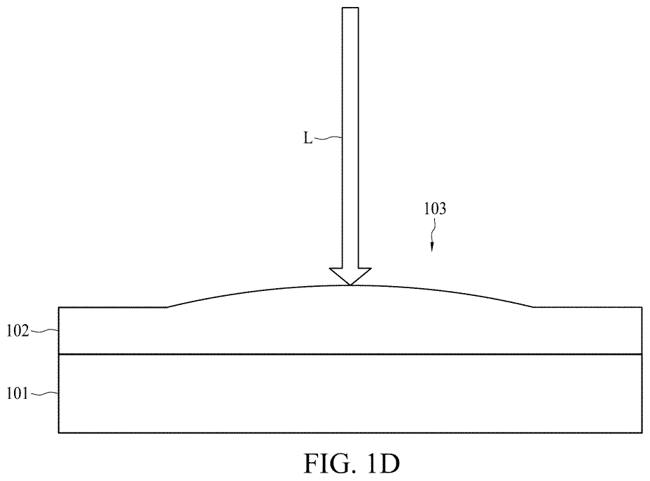

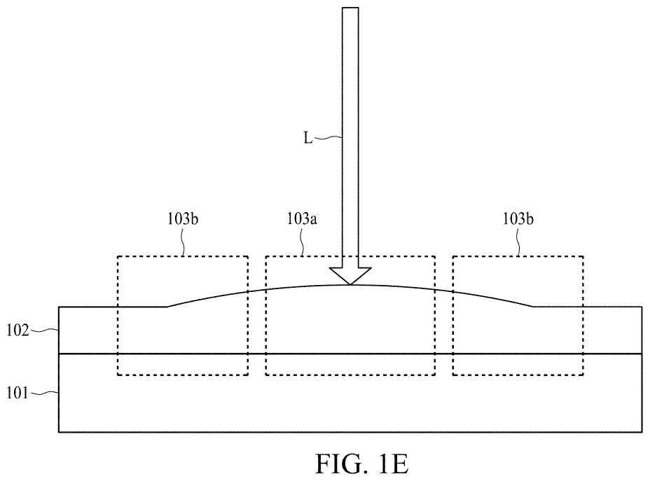

FIG. 1A to FIG. 1E are a flowchart of an optical control method according to the present invention. In FIG. 1A, a light controllable layer 102 is formed on a carrier 101, and the light controllable layer 102 is patterned to form at least one light controllable element. A carrier 101 is provided. The carrier 101 may be a single crystal substrate. In an embodiment, the carrier 101 may be a single crystal substrate such as silicon (Si), aluminum oxide (Al₂O₃) or lanthanum aluminate (LaAlO₃).

FIG. 1B is an enlarged view of a light controllable element A in FIG. 1A. The light controllable element A includes the carrier 101 and the light controllable layer 102. The light controllable layer 102 has one or more properties that may be controlled by a light beam. The control performed on the light controllable layer 102 by the light beam is reversible. The light controllable layer 102 may be a thin film grown on the carrier 101. The thickness of the thin film may be less than 800 nanometers (nm). In an embodiment, the thickness of the thin film may be less than 200 nm. In an embodiment, the thickness of the thin film may be between 10 nm and 150 nm.

The light controllable layer 102 may be formed on the carrier 101 in various manners. For example, the light controllable layer 102 may be formed on the carrier 101 by using any one of the following methods: sputtering, pulsed laser deposition (PLD), molecular beam epitaxy (MBE), spin coating, a sol-gel process, and metal organic chemical vapor phase deposition (MOCVD). In addition, the light controllable layer 102 may be formed on the carrier 101 by other growth or deposition methods.

In an embodiment, the light controllable layer 102 may be a functional material having a metal-insulator phase transition, a ferroelectric material having a long-range ordered electric dipole property, a ferromagnetic material having long-range ordered magnetism or a multiferroic material that simultaneously has two or more ferroic order parameters. In an embodiment, the light controllable layer 102 includes at least one of the following: a ferroelectric material, a ferromagnetic material, and a multiferroic material.

In an embodiment, the ferroelectric material of the light controllable layer 102 may be barium titanate (BaTiO₃), lead titanate (PbTiO₃), a lead zirconate titanate compound, and/or the like.

In an embodiment, the ferromagnetic material of the light controllable layer 102 includes materials such as ferroferric oxide (Fe₃O₄) and/or cobalt ferrite (CoFe₂O₄).

In an embodiment, the multiferroic material of the light controllable layer 102 includes bismuth ferrite (BiFeO₃, BFO), yttrium manganate (YMnO₃), and/or the like.

In an embodiment, the functional material having a metal-insulator phase transition of the light controllable layer 102 includes materials such as vanadium dioxide (VO₂) and/or lanthanum strontium manganese oxide (La₁₋ₓSrₓO₃).

In FIG. 1C, a light beam L is used for illuminating the light controllable layer 102. The light beam L has a specific wavelength range. In an embodiment, the wavelength of the light beam L is between 10 nm and 10 μm. In an embodiment, the wavelength of the light beam L is between 390 nm and 700 nm, and the light beam L may be visible light. In an embodiment, the wavelength of the light beam L is between 490 nm and 570 nm, and the light beam L may be green light emitted by a green laser.

An incident light spot is formed at an incident position where the light beam L illuminates the surface of the light controllable layer 102. The size of the light beam L may be less than or equal to that of the light controllable element. In an embodiment, the diameter of the incident light spot is between 50 nm and 10 μm. In an embodiment, the diameter of the incident light spot is between 1 μm and 5 μm. In an embodiment, the diameter of the incident light spot is between 1 μm and 2 μm.

In FIG. 1D, since the light beam L illuminates the light controllable layer 102 under a specific illumination power and illumination time, energy of the light beam L is converted into thermal energy. The generated thermal energy would spread out from the incident light spot of the light beam L (which is the center of spreading), causing the light controllable layer 102 to form a deformation area 103 due to heat expansion or a phase change.

Since the thermal energy generated by the light beam L spreads out from the incident light spot of the light beam L, the thermal energy is not simultaneously and evenly distributed on the light controllable element. Accordingly, a relatively large amount of thermal energy and deformation are accumulated in a position close to the incident light spot of the light beam L, while in a position that is relatively farther away from the incident light spot, there is a relatively small amount of thermal energy and deformation. Therefore, there are different degrees of heat expansion and deformation for positions closer to or farther away from the incident light spot. As shown in FIG. 1E, there is relatively significant heat expansion in a central portion 103a, close to the incident light spot of the light beam L, of the deformation area 103. In comparison, a degree of heat expansion in an edge portion 103b, relatively farther away from the incident light spot, of the deformation area 103 is relatively small. That is, the overall thickness of the central portion 103a is greater than the overall thickness of the edge portion 103b, and there are different amounts of deformation at the center and edge/periphery of the light controllable element.

The light controllable element is illuminated by a light beam to generate deformation, so that the light controllable element may be used to write information, for example, to turn a state “0” into a state “1”. According to properties of a material, the written state may be reversible or irreversible. This may be applied to a non-volatile memory or Radio Frequency Identification (RFID).

Different degrees of heat expansion apply different degrees of strain to the central portion 103a and the edge portion 103b of the deformation area 103. That is, the deformation area 103 has a strain gradient. As described in the following paragraphs, based on an equivalent electric field (a built-in electric field) caused by a flexoelectric effect, the strain gradient of the deformation area 103 causes a change in one or more properties of the light controllable layer 102, or the central portion 103a and the edge portion 103b of the deformation area 103 show different physical or electromagnetic properties.

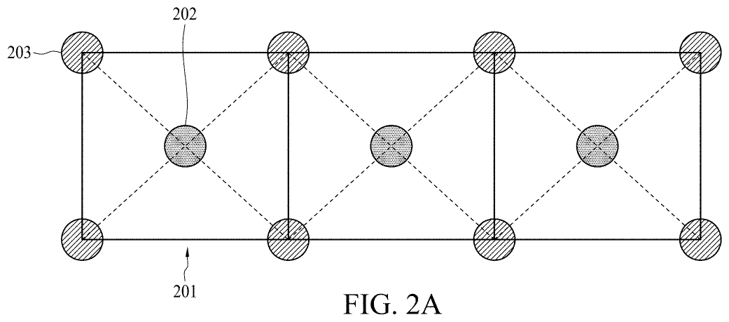

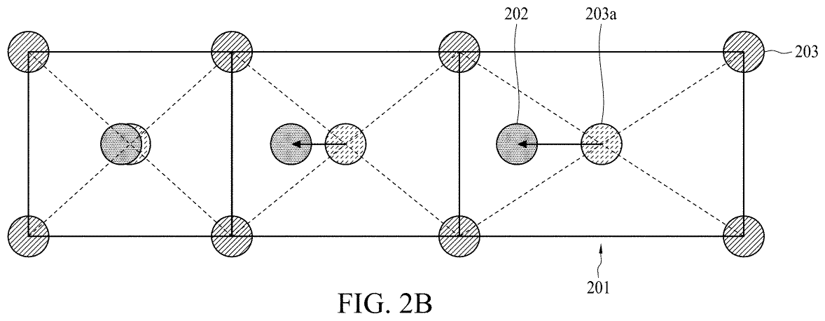

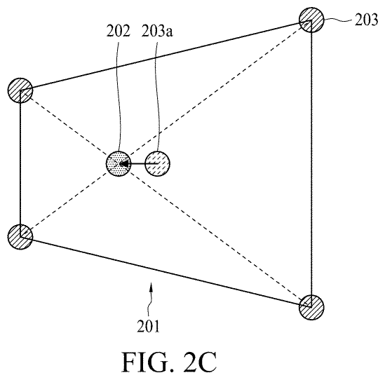

FIG. 2A to FIG. 2C are a schematic diagram of the principle of a flexoelectric effect. FIG. 2A shows a crystal structure that is not subject to an external force. Each crystal lattice 201 has a cation 202 and an anion 203. As a result of the symmetry of a crystal lattice structure, positions of a net negative charge and a net positive charge (namely, the cation 202) of each crystal lattice 201 overlap. Therefore, no electric dipole moment is generated.

FIG. 2B shows a crystal structure that is subject to external forces from the same direction, which causes one-dimensional deformation of the structure. Due to crystal lattice deformation, the position of a net negative charge 203a and the position of the net positive charge (namely, the cation 202) does not overlap. Therefore, an electric dipole moment pointing from the net negative charge 203a to the cation 202 is generated inside each crystal lattice 201 (see the arrow pointing from the net negative charge 203a to the cation 202). The rightmost crystal lattice 201 is subject to a largest external force, thereby generating the largest crystal lattice deformation. Therefore, a distance between the net negative charge 203a and the cation 202 is the largest, and thus the rightmost crystal lattice 201 has the largest electric dipole moment.

FIG. 2C shows a crystal structure that is subject to external force from different directions, which causes two-dimensional deformation. A strain applied to the left side of the crystal lattice 201 is different from a strain applied to the right side of the crystal lattice 201, causing crystal lattice deformation, and thus the positions of the net negative charge 203a and of the net positive charge (namely, the cation 202) do not overlap. Accordingly, an electric dipole moment pointing from the net negative charge 203a to the cation 202 is generated inside the crystal lattice 201. It can be learned from FIG. 2C that a direction of the strain gradient inside the crystal lattice 201 is opposite to that of an electric dipole moment.

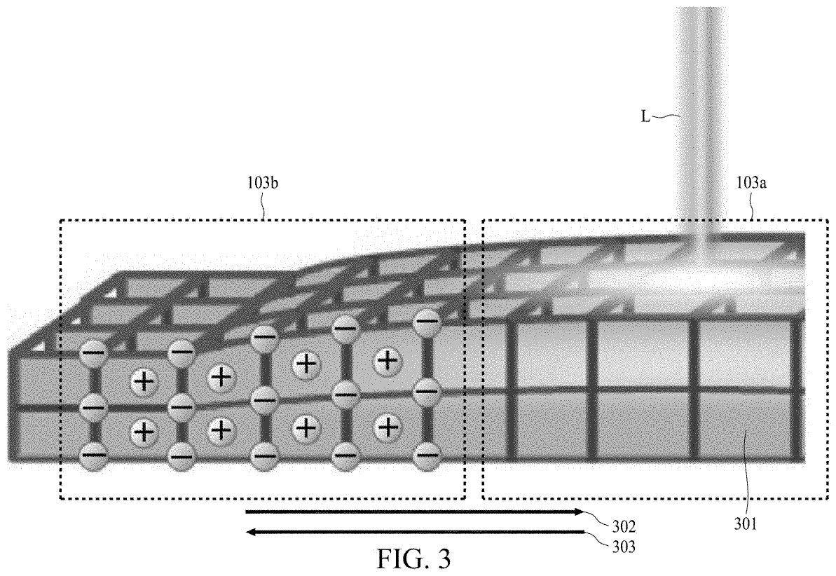

FIG. 3 shows a relationship between a strain gradient and an electric dipole moment in a light controllable layer 102 after illumination. As shown in FIG. 3, a central portion 103a has relatively significant heat expansion and deformation, and the degree of heat expansion of an edge portion 103b is relatively small. Different degrees of heat expansion cause different strains in the central portion 103a and the edge portion 103b. That is, the deformation area 103 of the light controllable layer 102 has a strain gradient, and the strain gradient points from the edge portion 103b of the deformation area 103 to the central portion 103a, as shown in a strain gradient direction 302. In addition, microscopically, the light controllable layer 102 is formed by a plurality of crystal lattices 301. FIG. 3 shows spatial distribution of cations and anions of crystal lattices 301 in the edge portion 103b (as shown in positions of positive and negative symbols). As can be seen from the principle of the flexoelectric effect shown in FIG. 2A to FIG. 2C, an electric dipole moment direction is opposite to a strain gradient direction, so that the deformation area 103 of the light controllable layer 102 has an electric dipole moment pointing from the central portion 103a to the edge portion 103b, as shown in an electric dipole moment direction 303.

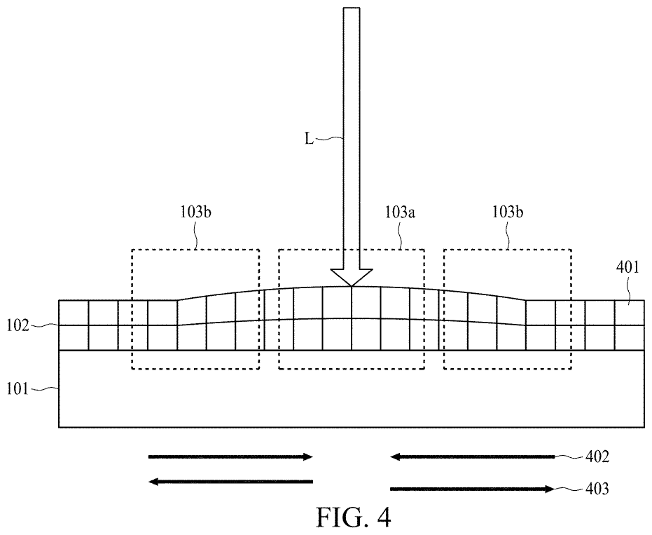

FIG. 4 shows a result obtained by applying a flexoelectric effect theoretical model to the light controllable layer 102 in FIG. 1E. As shown in FIG. 4, the deformation area 103 of the light controllable layer 102 has a strain gradient, and the strain gradient points from the edge portion 103b of the deformation area 103 to the central portion 103a, as shown in a strain gradient direction 402. In addition, microscopically, the light controllable layer 102 is formed by a plurality of crystal lattices 401. The deformation area 103 of the light controllable layer 102 has an electric dipole moment pointing from the central portion 103a to the edge portion 103b, as shown in an electric dipole moment direction 403. Because of the deformation area 103 of the light controllable layer 102 has an electric dipole moment pointing from the central portion 103a to the edge portion 103b, it can be learned that the deformation area 103 has built-in electric fields in the same direction (pointing from the central portion 103a to the edge portion 103b), that is, the built-in electric field points around with the incident light spot of the light beam L as the center.

The electric dipole moment and the built-in electric field are generated in the light controllable layer 102 due to the flexoelectric effect, so that the one or more properties of the light controllable layer 102 are changed, or the central portion 103a and the edge portion 103b of the deformation area 103 show different physical or electromagnetic properties.

In an embodiment, the light controllable layer 102 may be a functional material having a metal-insulator phase transition, a ferroelectric material, a ferromagnetic material, and/or a multiferroic material. An electric dipole moment and a built-in electric field are generated in the light controllable layer 102 due to the flexoelectric effect. This causes the central portion 103a and the edge portion 103b of the deformation area 103 to show different ferroelectricity, antiferromagnetism, and/or magnetism, and the like. In an embodiment, the light controllable layer 102 is a BFO thin film After being illuminated, the BFO thin film has the deformation area 103, and a central portion 103a and an edge portion 103b show different ferroelectricity, antiferromagnetism, and/or magnetism. For the ferroelectricity, ferroelectric polarization of the central portion 103a is relatively small, and the ferroelectric polarization of the edge portion 103b is relatively large. For the antiferromagnetism, a Neel temperature (antiferromagnetic property temperature) of the central portion 103a is relatively low, and a Neel temperature of the edge portion 103b is relatively high. For magnetism, magnetism of the central portion 103a is relatively weak, and magnetism of the edge portion 103b is relatively strong. In an embodiment, the light controllable layer 102 is an oxide thin film, for example, vanadium dioxide (VO₂) or vanadium trioxide (V₂O₃). After being illuminated, the oxide thin film has the deformation area 103. The central portion 103a and the edge portion 103b show different conductive properties, the conductibility of the central portion 103a is relatively low, and the conductibility of the edge portion 103b is relatively high.

All property changes of the light controllable layer 102 after illumination are reversible. That is, after illumination is removed, a property change caused by the illumination may retain for a long time, so that the light controllable layer 102 has a non-volatile memory property. Therefore, if a property in a target position of the light controllable layer 102 needs to be changed, it is only necessary to control the illumination to change an incident position of the light beam L, so that the position, size, and shape of the deformation area can be changed, and a property change of the light controllable layer 102 is effectively controlled.

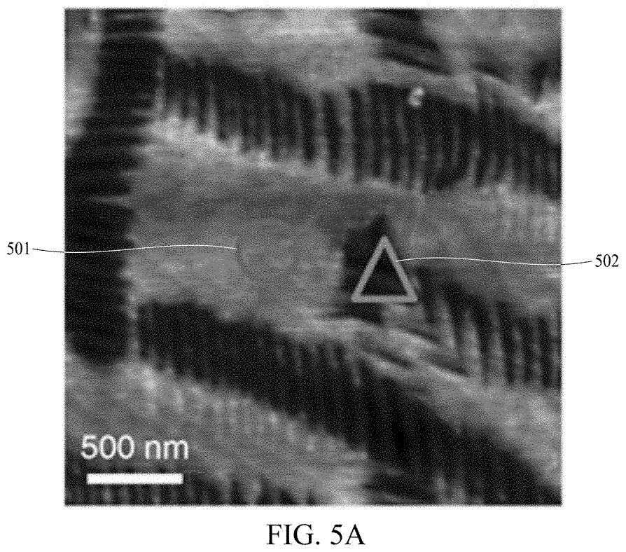

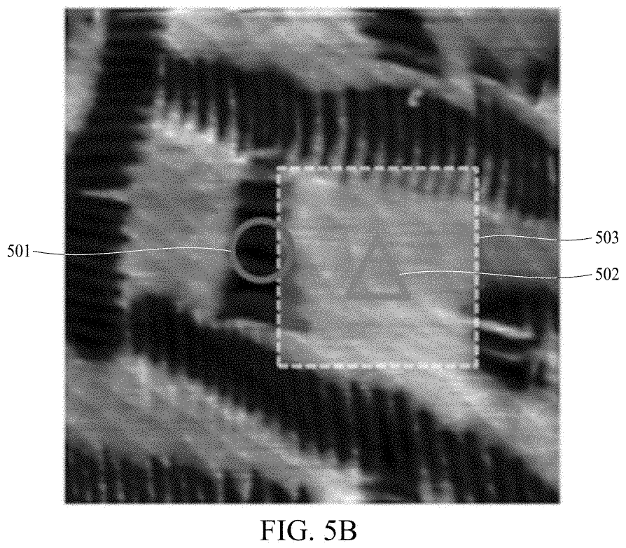

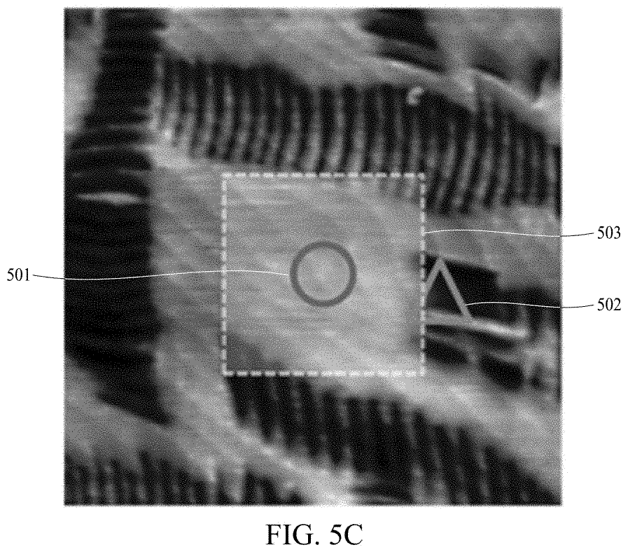

FIG. 5A to FIG. 5C are a schematic diagram of a property change of a light controllable layer 102 when an incident position of a light beam L is changed. When a BFO thin film grows on a lanthanum aluminate substrate, because the dimension of a lanthanum aluminate crystal lattice is less than that of BFO. With the effect of a strain of the lanthanum aluminate substrate, the BFO thin film may grow into a tetragonal-like phase and a rhombohedral-like phase. A position in which tetragonal-like phase BFO and rhombohedral-like phase BFO simultaneously occur is referred to as mixed-phase BFO, and different phases of BFO show different physical or electromagnetic properties. FIG. 5A shows a BFO thin film grown on the lanthanum aluminate substrate before the illumination. The flat pattern is tetragonal-like phase BFO, and the stripe pattern is mixed-phase BFO. In FIG. 5A, a first position (the position of the circle) 501 is tetragonal-like phase BFO, and a second position (the position of the triangle) 502 is mixed-phase BFO.

In FIG. 5B, a light beam L is used for incidence in the second position 502, and an illumination area is marked as 503. Due to a flexoelectric effect, a central portion and an edge portion of a deformation area of the BFO thin film show different properties. The second position 502 located at the central portion of the deformation area is transformed from the stripe pattern in FIG. 5A into a flat pattern, that is, the BFO thin film in the second position 502 is transformed from mixed-phase BFO into tetragonal-like phase BFO. In comparison, the first position 501 located at the edge portion of the deformation area is transformed from the flat pattern shown in FIG. 5A into a stripe pattern, that is, is transformed from tetragonal-like phase BFO into mixed-phase BFO. In other words, one light controllable element may form multi-position memory cells due to phase distribution with polymorphism.

In FIG. 5C, the incident position of the light beam L is changed, so that the first position 501 is located at the center of the illumination area 503. As shown in the figure, the first position 501 located at the central portion is transformed from the stripe pattern shown in FIG. 5B into a flat pattern, that is, the BFO thin film in the first position 501 is transformed from mixed-phase BFO into tetragonal-like phase BFO. In comparison, the second position 502 located at the edge portion is transformed from the flat pattern shown in FIG. 5B into a stripe pattern, that is, is transformed from tetragonal-like phase BFO into mixed-phase BFO. In addition, the light beam L may also be caused to perform illumination in different positions of the light controllable layer 102 in sequence to simultaneously change the position, size, and shape of a deformation area. For example, the light beam L is caused to generate a stripe-shaped deformation area on the light controllable layer 102, to effectively control a property change of the light controllable layer 102.

As shown in FIG. 5A to FIG. 5C, the light controllable layer shows different property changes in different positions (for example, the first position 501 and the second position 502) after illumination, and different combinations of the property changes correspond to a plurality of different memory states. That is, the light controllable layer has a non-volatile memory property, and may be used as an optical control device or a memory device, and the different positions (for example, the first position 501 and the second position 502) may be used as different memory units. Therefore, if a property in a position on the light controllable layer needs to be changed, it is only necessary to control illumination to change an incident position of the light beam, so that the property change of the light controllable layer 102 can be effectively controlled. Therefore, the memory device disclosed in the present invention may be used to erase or write within a memory unit or element in a contactless illumination manner.

In addition, the light controllable memory device disclosed in the present invention may substantially improve memory density. For example, the central portion and the edge portion of the deformation area of the BFO thin film after illumination show different ferroelectricity, antiferromagnetism, and magnetism. The three properties are independently controlled in a light controllable manner, different combinations of the three properties may correspond to eight different memory states. There are much more memory states than the only two memory states of “1” representing a high potential and “0” representing a low potential of a conventional memory unit. In addition, the memory device completed in a light controllable manner may also overcome a data loss of conventional memory caused by problems such as a leakage current.

A person skilled in this technology can conceive of other embodiments without departing from the scope of the appended claims.

### DESCRIPTIONS OF SYMBOLS

101: Carrier
102: Light controllable layer
103: Deformation area
103a: Central portion
103b: Edge portion
201: Crystal lattice
202: Cation
203: Anion
203a: Net negative charge
301: Crystal lattice
302: Strain gradient direction
303: Electric dipole moment direction
401: Crystal lattice
402: Strain gradient direction
403: Electric dipole moment direction
501: First position 501
502: Second position 502
503: Illumination area 503
L: Light beam

What is claimed is:

1. An optoelectronic device, comprising:
a carrier; and
a light controllable layer patterned to be formed on the carrier to form at least one light controllable element,
wherein the at least one light controllable element is independently controllable by a light beam so that the at least one light controllable element is switchable between two or more states.

2. The optoelectronic device according to claim 1, wherein the light controllable layer comprises at least one of the following materials: a functional material having a metal-insulator phase transition, a ferroelectric material, a ferromagnetic material, and a multiferroic material.

3. The optoelectronic device according to claim 2, wherein the ferroelectric material comprises barium titanate (BaTiO₃), lead titanate (PbTiO₃) or a lead zirconate titanate compound.

4. The optoelectronic device according to claim 2, wherein the ferromagnetic material comprises ferroferric oxide (Fe₃O₄) or cobalt ferrite (PbTiO₃).

5. The optoelectronic device according to claim 2, wherein the multiferroic material comprises bismuth ferrite (BiFeO₃, BFO) or yttrium manganate (YMnO₃).

6. The optoelectronic device according to claim 2, wherein the functional material having a metal-insulator phase transition comprises vanadium dioxide (VO₂) and/or lanthanum strontium manganese oxide (La₁₋ₓSrₓO₃).

7. The optoelectronic device according to claim 1, wherein the light controllable layer comprises at least one of the following physical properties: ferroelectricity, antiferromagnetism, magnetism, and conductibility.

8. The optoelectronic device according to claim 1, wherein the switching between the two or more states is nonvolatile.

9. The optoelectronic device according to claim 1, wherein illumination of the light beam on the at least one light controllable element causes deformation in the light controllable layer.

10. The optoelectronic device according to claim 9, wherein each of the at least one light controllable element has different amounts of deformation in a geometrically central portion of the light controllable element and a geometrically peripheral portion of the light controllable element.

11. The optoelectronic device according to claim 10, wherein the one or more properties of each of the at least one light controllable element are different in the geometrically central portion of the light controllable element and the geometrically peripheral portion of the light controllable element.

12. The optoelectronic device according to claim 1, wherein the thickness of at least one of the at least one light controllable element in a geometrically central portion of the light controllable element is greater than the thickness in a geometrically peripheral portion of the light controllable element.

13. The optoelectronic device according to claim 1, wherein the light controllable layer comprises an oxide material.

14. The optoelectronic device according to claim 1, wherein the wavelength of the light beam is between 10 nm and 10 μm.

15. The optoelectronic device according to claim 1, wherein the wavelength of the light beam is between 390 nm and 700 nm.

16. The optoelectronic device according to claim 1, wherein the wavelength of the light beam is between 490 nm and 570 nm.
